(19) United States
(12) Patent Application Publication
(10) Pub. No.: US 2016/0155713 A1
(43) Pub. Date: Jun. 2, 2016

(54) SEMICONDUCTOR PACKAGE AND METHOD OF MANUFACTURING THE SAME

(71) Applicant: Samsung Electro-Mechanics Co., Ltd., Suwon-si (KR)

(72) Inventors: Hyeong Taek KIM, Suwon-si (KR); Se Jong KIM, Suwon-si (KR)

(73) Assignee: Samsung Electro-Mechanics Co., Ltd., Suwon-si (KR)

(21) Appl. No.: 14/953,962

(22) Filed: Nov. 30, 2015

(30) Foreign Application Priority Data
Dec. 2, 2014 (KR) 10-2014-0170523

(51) Int. Cl. H01L 23/64; H01L 21/56; H01L 49/02; H01L 23/538; H01L 23/28

(52) U.S. Cl. CPC H01L 23/645; H01L 23/5384; H01L 23/28; H01L 28/10; H01L 21/563

(57) ABSTRACT

A semiconductor package includes: a board; a sealing member disposed on the board; at least one chip member mounted on the board and embedded in the sealing member; and at least one inductor embedded in the sealing member and disposed over a chip member among the at least one chip member.

### CROSS-REFERENCE TO RELATED APPLICATION(S)

This application claims the benefit of Korean Patent Application No. 10-2014-0170523 filed on Dec. 2, 2014 in the Korean Intellectual Property Office, the entire disclosure of which is incorporated herein by reference for all purposes.

### BACKGROUND

1. Field

The following description relates to a semiconductor package and a method of manufacturing the same.

2. Description of Related Art

Recently, due to advancements in information technology (IT), portable devices such as smartphones capable of performing a variety of functions have been continuously developed. In order for many devices to perform more functions while having a more compact size, sizes of internal electronic elements performing respective functions have gradually been reduced. Additionally, in order to effectively utilize space, the internal electronic elements have been packaged. An example of a semiconductor package is disclosed in Korean Patent Laid-Open Publication No. 10-2011-0076606.

Therefore, the development of a structure allowing for slimness and miniaturization of a semiconductor package has been continuously demanded.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a semiconductor package includes: a board; a sealing member disposed on the board; at least one chip member mounted on the board and embedded in the sealing member; and at least one inductor embedded in the sealing member and disposed over a chip member among the at least one chip member.

The inductor may include: a connection conductor connected to the board; and an inductor body connected to the connection conductor.

The inductor may be embedded in the sealing member by using an electroless plating method or a patterning method using a conductive paste.

The sealing member may include: a first sealing layer disposed on the board, the at least one chip member being embedded in the first sealing layer and the inductor being exposed through the first sealing layer; and a second sealing layer disposed on the first sealing layer, the inductor being embedded in the second sealing layer.

The inductor may be disposed in a portion of the first sealing layer having a thickness that is reduced in comparison to a thickness of other portions of the first sealing layer.

The chip member may have a height that is lower than a height of other chip members among the at least one chip member.

The sealing member may be formed of an epoxy molding compound (EMC).

The semiconductor package may further include a shield member embedded in the sealing member and disposed around the inductor.

The shield member may include a shield portion configured to shield the chip member, and a connection via connected to the board.

According to another general aspect, a method of manufacturing a semiconductor package includes: forming a via hole and a groove in a first sealing layer sealing at least one chip member; forming an inductor using a conductive material in the via hole and the groove; and forming a second sealing layer to embed the inductor in the second sealing layer.

The method may further include, before the forming of the via hole and the groove: preparing a board; mounting the at least one chip member on the board; and forming the first sealing layer to seal the at least one chip member.

The inductor may be embedded in the first sealing layer by performing an electroless plating operation or a patterning operation using a conductive paste.

The first and second sealing layers may be formed of an epoxy molding compound (EMC).

The forming of the inductor may include disposing the inductor over a chip member, among the at least one chip member, having a height that is lower than a height of other chip members among the at least one chip member.

The method may further include embedding a shield member in the second sealing layer around the inductor.

Other features and aspects will be apparent from the following detailed description, the drawings, and the claims.

### BRIEF DESCRIPTION OF THE DRAWINGS

FIG. 1 is a schematic cross-sectional view illustrating a semiconductor package, according to an example.

FIG. 2 is a schematic perspective view illustrating the semiconductor package of FIG. 1.

FIG. 3 is a view illustrating example operations of preparing a board and mounting a chip member of the semiconductor package, in a method of manufacturing the semiconductor package.

FIG. 4 is a view illustrating an example operation of forming a first sealing layer of the semiconductor package.

FIG. 5 is a view illustrating an example operation of forming a via hole and a groove in the first sealing layer of the semiconductor package.

FIG. 6 is a view illustrating an example operation of forming an inductor of the semiconductor package.

FIG. 7 is a view illustrating an example operation of forming a second sealing layer of the semiconductor package.

FIG. 8 is a view illustrating an example operation of performing surface-treatment on the second sealing layer of the semiconductor package.

FIG. 9 is a schematic cross-sectional view illustrating a semiconductor package, according to another example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

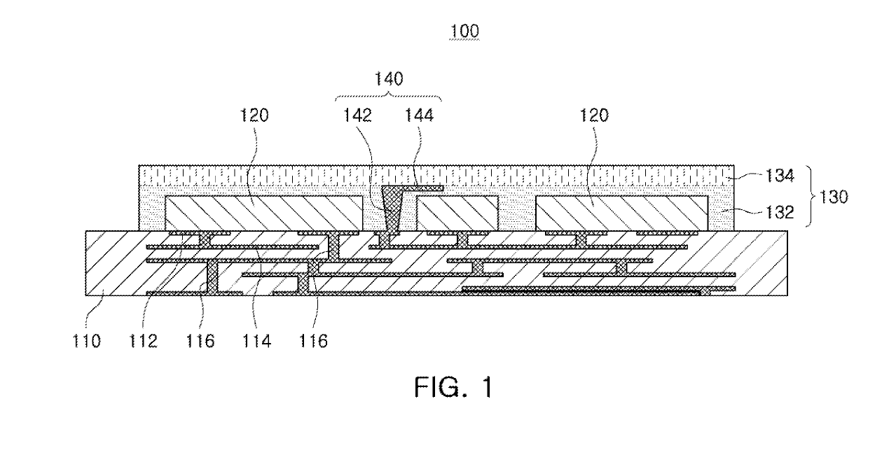

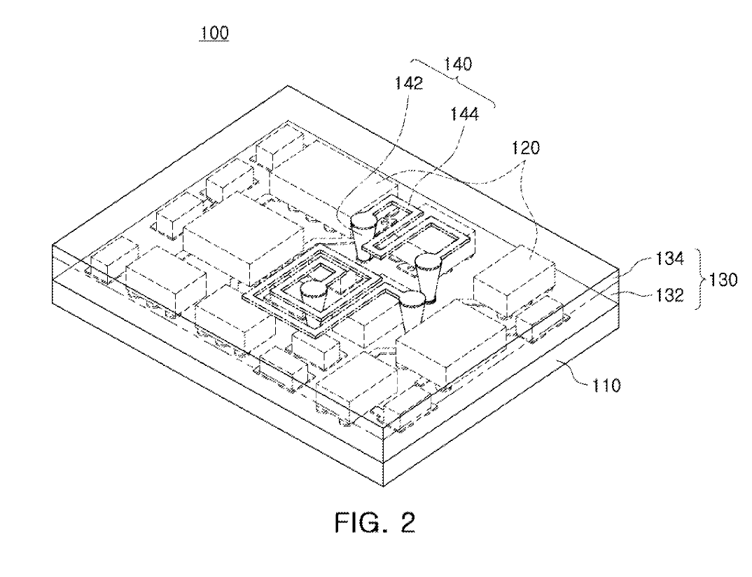

FIG. 1 is a schematic cross-sectional view illustrating a semiconductor package 100 according to an example, and FIG. 2 is a schematic perspective view illustrating the semiconductor package 100.

Referring to FIGS. 1 and 2, the semiconductor package 100 includes a board 110, one or more chip members 120, a sealing member 130, and an inductor 140.

The board 110, which is used for mounting the chip members 120 on at least one surface thereof, may be any one of various kinds of boards such as a ceramic board, a printed circuit board, a flexible board, and the like. Further, mounting electrodes 112 for mounting the chip members 120 or a wiring pattern (not illustrated) connecting the mounting electrodes to each other may be formed on at least one surface of the board 110. The board 110 may be a multilayer board including a plurality of layers, and circuit patterns 114 for forming an electrical connection may be formed between the layers. In addition, conductive vias 116 electrically connecting the mounting electrodes 112 and the circuit patterns 114 formed in the board 110 to each other may be provided in the board 110.

Although a case in which the board 110 is a multilayer board is illustrated by way of example in the accompany drawings, the board 110 is not limited to such a multilayer construction. Further, although a case in which the chip members 120 are mounted only on an upper surface of the board 110 is described by way of example, the chip members 120 are not limited to being mounted only on the upper surface of the board 110, and the board 110 may be a double-sided board with the at least one chip member 120 mounted on the upper surface and/or a lower surface thereof.

The chip members 120 are mounted on at least one surface of the board 110 and includes various elements such as passive elements and active elements. In addition, all of the elements may be used as the chip members 120 as long as they may be mounted on the board 110.

All of the chip members 120 as described above may be mounted on the upper surface of the board 110. The chip members 120 may be disposed in various forms on the board 110 depending on sizes or shapes of the chip members 120 and a design of the semiconductor package 100. For example, although a case in which a chip member 120 disposed in a central portion of the board 110 is lower than a chip member 120 disposed in an end portion thereof is illustrated by way of example in the drawings, the arrangement of the chip members 120 is not limited to the illustrated arrangement. In addition, the chip members 120 may be mounted on the board 110 in a flip-chip form or electrically bonded to the board 110 through a bonding wire.

The sealing member 130 is formed on the board 110 so that the chip members 120 are embedded therein. The sealing member 130 includes a first sealing layer 132 disposed on the board 110 to allow the chip members 120 to be embedded therein. The first sealing layer 132 may be formed after the chip members 120 are mounted on the board 110.

More specifically, the first sealing layer 132 seals the chip members 120 mounted on the board 110. Further, the first sealing layer 132 is provided between the chip members 120 mounted on the board 110, and thus the first sealing layer 132 prevents an electric short-circuit from occurring between the chip members 120 and encloses outer portions of the chip members 120 to fix the chip members 120 onto the board 110. Therefore, the first sealing layer 132 may prevent the chip members 120 from being damaged or separated from the board 110 by external impact.

The first sealing layer 132 is formed of an insulating material including, for example, a resin such as an epoxy resin, including an epoxy molding compound (EMC).

Although a case in which the first sealing layer 132 is formed on the upper surface of the board 110 so that all of the chip members 120 are embedded in the first sealing layer 132 is described herein, the first sealing layer 132 is not limited to this example, and may be variously modified. For example, the first sealing layer 132 may be configured so that at least one of the chip members 120 is partially exposed to the outside of the first sealing layer 132.

In addition, a via hole 132a and a groove 132b for forming an inductor 140, which is described below, is formed in the first sealing layer 132. The via hole 132a and the groove 132b may be formed by a laser drilling method after curing the first sealing layer 132. However, the method of forming the via hole 132a and the groove 132b is not limited to laser drilling, and the via hole 132a and the groove 132b may be formed by a chemical or physical etching method.

A second sealing layer 134 is formed on the first sealing layer 132 to embed the inductor 140. That is, the second sealing layer 134 is formed so as to embed the inductor 140 therein, thereby serving to prevent the inductor 140 from being damaged by external impact while fixing the inductor 140.

The second sealing layer 134 is also formed of an insulating material including a resin such as an epoxy resin, including, for example, an epoxy molding compound (EMC).

The inductor 140 is embedded in the sealing member 130 and disposed over a chip member 120, and more than one inductor 140 may be provided. More specifically, the inductor 140 may be embedded in the first sealing layer 132 at a portion of the first sealing layer 132 having a thickness that is reduced in comparison to other portions of the first sealing layer 132. Additionally, the inductor 140 may be disposed over a chip member 120 having a lower height than other chip members 120.

The inductor 140 is composed of connection conductors 142 connected to the board 110 and an inductor body 144 connected to the connection conductors 142. One end of the connection conductor 142 is connected to the mounting electrode 112 of the board 110, and the other end of the connection conductor 142 is connected to the inductor body 144. In other words, the inductor 140 is composed of two connection conductors 142 and the inductor body 144 connecting the connection conductors 142 to each other.

In addition, the inductor 140 is inserted into and formed in the via hole 132a and the groove 132b of the first sealing layer 132. That is, the connection conductor 142 is formed in the via hole 132a, and the inductor body 144 is formed in the groove 132b.

The connection conductor 142 and the inductor body 144 may be formed of the same material, or they may be formed of different materials. For example, the connection conductor 142 may be formed by printing a paste using a metal mask and curing the printed paste, and the inductor body 144 may be formed by using a silver paste. Alternatively, the inductor 140 may be formed by an electroless plating method or a patterning method using a conductive paste so as to be embedded in the sealing member 130.

As described above, the inductor 140 is formed in the sealing member 130 in a portion of the first sealing layer 132 having a reduced thickness (in the groove 132b), and is provided over a chip member 120 having a reduced height. Accordingly, miniaturization and slimness of the semiconductor package 100 may be achieved.

Hereinafter, a method of manufacturing a semiconductor package according to an example embodiment will be described with reference to the accompanying drawings.

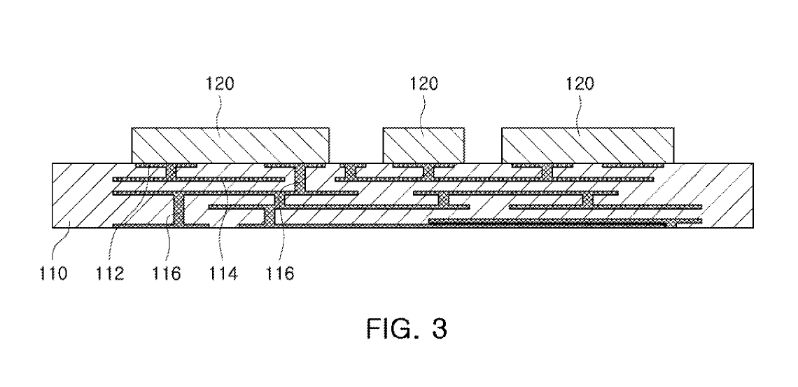

FIGS. 3 through 9 are views illustrating an example method of manufacturing the semiconductor package 100. Hereinafter, the method of manufacturing the semiconductor package 100 will be described sequentially with reference to FIGS. 3 through 9.

FIG. 3 is a view illustrating example operations of preparing the board 110 and mounting the chip member 120.

Referring to FIG. 3, first, the board 110 is prepared, and the chip members 120 are mounted on one surface of the board 110. The board 110 may be any one of various kinds of boards such as a ceramic board, a printed circuit board, or a flexible board. Although the chip members 120 are shown and described as being mounted only on an upper surface of the board 110, the chip members 120 may be mounted on the lower surface of the board 110, or on the upper and lower surfaces of the board 110.

Further, mounting electrodes 112 for mounting the chip members 120 or a wiring pattern (not illustrated) connecting the mounting electrodes 112 to each other are formed on at least one surface of the board 110.

The board 110 is a multilayer board including a plurality of layers, and circuit patterns 114 for forming an electrical connection are formed between the layers. In addition, conductive vias 116 electrically connecting the mounting electrodes 112 and the circuit patterns 114 to each other are provided in the board 110.

Although the board 110 is shown and described as being a multilayer board, the board 110 is not limited thereto.

The chip members 120 are mounted on at least one surface of the board 110 and include various elements such as passive elements and active elements. In addition, all of the elements may be used as the chip members 120 as long as they may be mounted on the board 110.

All of the chip members 120 as described above may be mounted on the upper surface of the board 110. The chip members 120 may be disposed in various forms on the board 110 depending on sizes or shapes of the chip members 120 and a design of the semiconductor package 100. That is, although a case in which a chip member 120 disposed in a central portion of the board 110 is lower than a chip member 120 disposed in an end portion thereof is illustrated in the drawings, the arrangement of the chip members 120 is not limited thereto. In addition, the chip members 120 may be mounted on the board 110 in a flip-chip form or electrically bonded to the board 110 through a bonding wire.

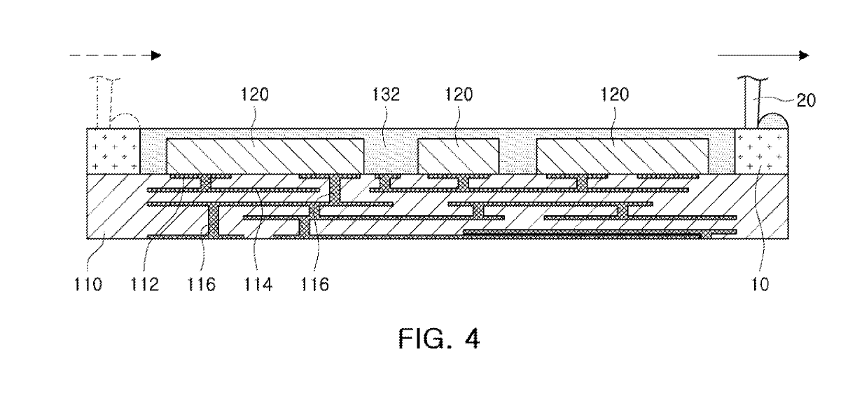

FIG. 4 is a view illustrating an example operation of forming the first sealing layer 132 of the semiconductor package 100 according to the exemplary embodiment.

As illustrated in FIG. 4, after forming a metal mask 10 on an edge of the board 110, the first sealing layer 132 is formed by applying an insulating material in an internal space formed by the metal mask 10, and curing the insulating material. The first sealing layer 132 is formed of an insulating material including a resin such as an epoxy resin, including an epoxy molding compound (EMC). Further, the insulating material is applied using an application member 20.

The first sealing layer 132 is formed on the board 110 so that the chip members 120 are embedded therein. That is, the first sealing layer 132 is provided between the chip members 120 mounted on the board 110, and thus the first sealing layer 132 prevents an electric short-circuit from occurring between the chip members 120 and encloses the chip members 120 to fix the chip members 120 onto the board 110. Therefore, the first sealing layer 132 may prevent the chip member 120 from being damaged or separated from the board 110 by external impact.

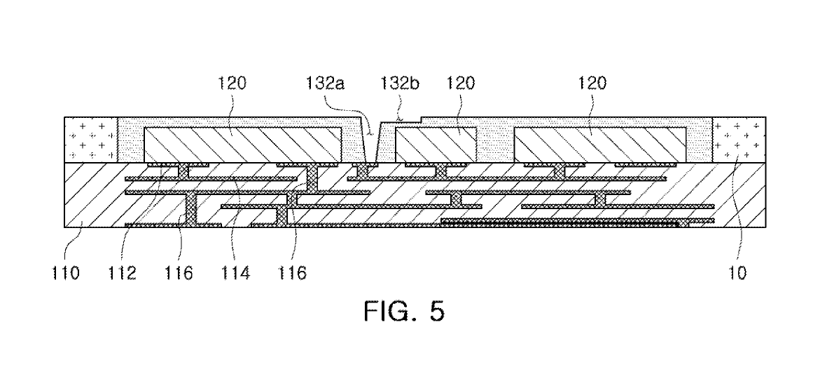

FIG. 5 is a view illustrating an example operation of forming the via hole 132a and the groove 132b in the first sealing layer 132

Referring to FIG. 5, the via hole 132a and the groove 132b are formed in the first sealing layer 132. The via hole 132a and the groove 132b may be formed by a laser drilling method or a chemical or physical etching method. The via hole 132a is formed to expose the mounting electrode 112 of the board 110, and the groove 132b is connected to the via hole 132a and disposed in a direction parallel to the board 110.

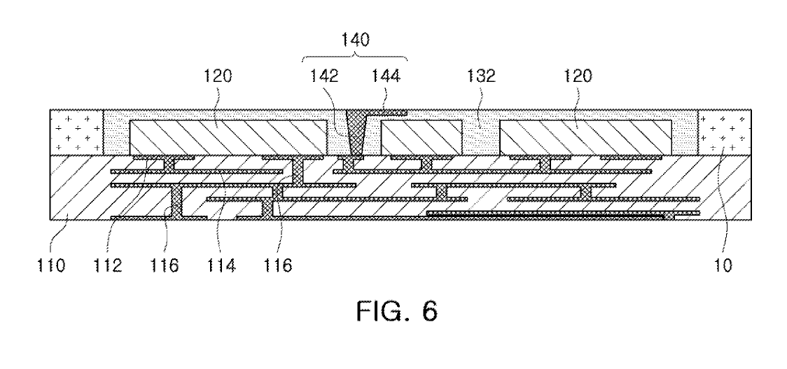

FIG. 6 is a view illustrating an example operation of forming the inductor 140 of the semiconductor package 100.

Referring to FIG. 6, the connection conductors 142 and the inductor body 144 are formed in the via hole 132a and the groove 132b, thereby forming the inductor 140. The inductor 140 is formed, for example, on the first sealing layer 132 by an electroless plating method or a patterning method using a conductive paste. The connection conductors 142 and the inductor body 144 may be formed of the same material, or they may be formed of different materials. For example, the connection conductors 142 may be formed by printing a paste using a metal mask and curing the printed paste, and the inductor body 144 may be formed by using a silver paste.

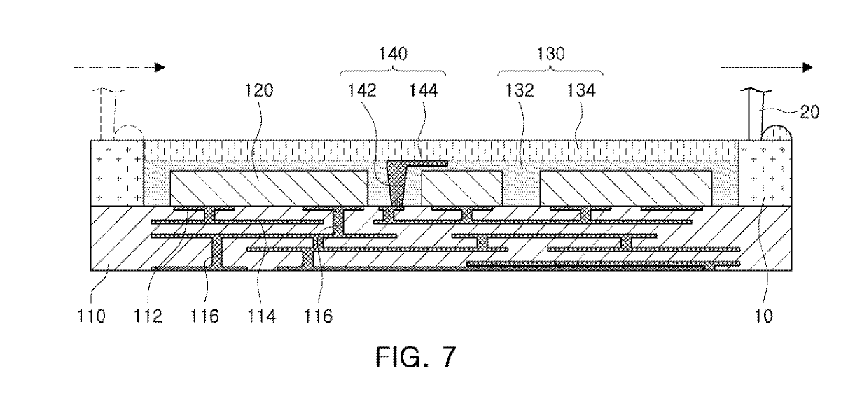

FIG. 7 is a view illustrating an example operation of forming the second sealing layer 134 of the semiconductor package 100.

Referring to FIG. 7, when the inductor 140 is formed, the second sealing layer 134 is formed on the first sealing layer 132 using the metal mask 10 and the application member 20. That is, an insulating material for forming the second insulating layer 134 is applied in an internal space formed by the metal mask 10. Therefore, the inductor 140 is embedded in the second sealing layer 134.

The second sealing layer 134 is also formed of an insulating material including a resin such as an epoxy resin, including an epoxy molding compound (EMC).

As described above, the second sealing layer 134 is formed so as to embed the inductor 140, thereby serving to prevent the inductor 140 from being damaged by external impact while fixing the inductor 140.

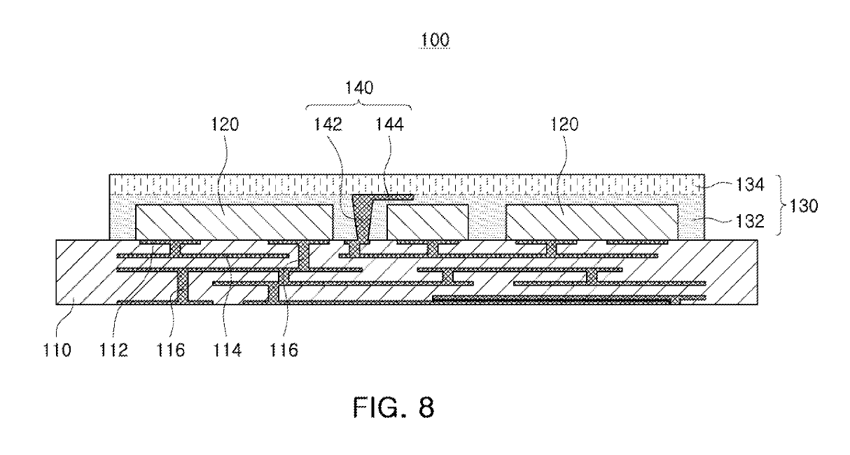

FIG. 8 is a view illustrating an example operation of performing surface-treatment on the second sealing layer 134.

Referring to FIG. 8, when the second sealing layer 134 is formed, the second sealing layer 134 is cured by heat, or the like. Thereafter, the second sealing layer 134 may be provided with a smooth surface by performing surface-treatment on the cured second sealing layer 134. The surface-treatment may be performed by a chemical or mechanical grinding method.

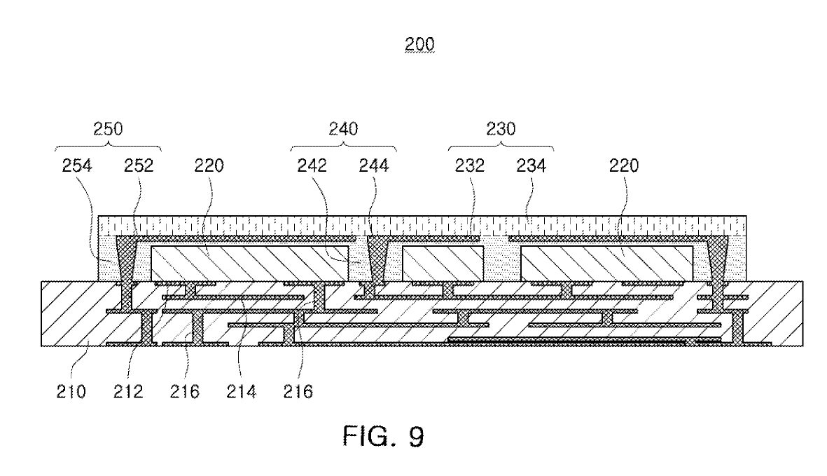

Hereinafter, a semiconductor package 200 according to another example will be described with reference to the accompanying FIG. 9.

FIG. 9 is a schematic cross-sectional view illustrating the semiconductor package 200.

Referring to FIG. 9, the semiconductor package 200 includes a board 210, one or more chip members 220, a sealing member 230, an inductor 240 including connection conductors 242 and an inductor body 244, and a shield member 250. Since the board 210, the chip member 220, the sealing member 230, and the inductor 240 are the same as the board 110, the chip member 120, the sealing member 130, and the inductor 140 described in the previous embodiment, a detailed description thereof will be omitted.

The shield member 250 is embedded in the sealing member 230 so as to be disposed around the inductor 240. That is, the shield member 250 is formed on a first sealing layer 232 of the sealing member 230 and embedded in a second sealing layer 234 of the sealing member 230.

The shield member 250 includes a shield portion 252 shielding an upper portion of a chip member 120 and a connection via 254 extended from the shield portion 252 so as to be connected to the board 210. More than one shield member 250 may be provided.

The shield member 250 serves as a ground and may serve to prevent electromagnetic waves from being externally leaked or internally introduced.

As set forth above, according to exemplary embodiments, slimness of the semiconductor package may be obtained by the inductor formed as the pattern in the sealing layer.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor package comprising:
a board;
a sealing member disposed on the board;
at least one chip member mounted on the board and embedded in the sealing member; and
at least one inductor embedded in the sealing member and disposed over a chip member among the at least one chip member.

2. The semiconductor package of claim 1, wherein the inductor includes:
a connection conductor connected to the board; and
an inductor body connected to the connection conductor.

3. The semiconductor package of claim 2, wherein the inductor is embedded in the sealing member by using an electroless plating method or a patterning method using a conductive paste.

4. The semiconductor package of claim 2, wherein the sealing member includes:
a first sealing layer disposed on the board, the at least one chip member being embedded in the first sealing layer and the inductor being exposed through the first sealing layer; and
a second sealing layer disposed on the first sealing layer, the inductor being embedded in the second sealing layer.

5. The semiconductor package of claim 4, wherein the inductor is disposed in a portion of the first sealing layer having a thickness that is reduced in comparison to a thickness of other portions of the first sealing layer.

6. The semiconductor package of claim 4, wherein the chip member has a height that is lower than a height of other chip members among the at least one chip member.

7. The semiconductor package of claim 1, wherein the sealing member is formed of an epoxy molding compound (EMC).

8. The semiconductor package of claim 1, further comprising a shield member embedded in the sealing member and disposed around the inductor.

9. The semiconductor package of claim 8, wherein the shield member comprises a shield portion configured to shield the chip member, and a connection via connected to the board.

10. A method of manufacturing a semiconductor package, comprising:
forming a via hole and a groove in a first sealing layer sealing at least one chip member;
forming an inductor using a conductive material in the via hole and the groove; and
forming a second sealing layer to embed the inductor in the second sealing layer.

11. The method of claim 10, further comprising, before the forming of the via hole and the groove:
preparing a board;
mounting the at least one chip member on the board; and
forming the first sealing layer to seal the at least one chip member.

12. The method of claim 10, wherein the inductor is embedded in the first sealing layer by performing an electroless plating operation or a patterning operation using a conductive paste.

13. The method of claim 10, wherein the first and second sealing layers are formed of an epoxy molding compound (EMC).

14. The method of claim 10, wherein the forming of the inductor comprises disposing the inductor over a chip member, among the at least one chip member, having a height that is lower than a height of other chip members among the at least one chip member.

15. The method of claim 10, further comprising embedding a shield member in the second sealing layer around the inductor.
